(19) United States
(12) Patent Application Publication
(10) Pub. No.: US 2025/0234729 A1
(43) Pub. Date: Jul. 17, 2025

(54) DISPLAY DEVICE

(71) Applicant: Samsung Display Co., LTD., Yongin-si (KR)

(72) Inventors: Kyung Ho PARK, Yongin-si (KR); Hyung Jin SONG, Yongin-si (KR); Soo Hong CHEON, Yongin-si (KR)

(73) Assignee: Samsung Display Co., LTD., Yongin-si (KR)

(21) Appl. No.: 18/906,595

(22) Filed: Oct. 4, 2024

(30) Foreign Application Priority Data
Jan. 16, 2024 (KR) 10-2024-0006710

(51) Int. Cl. H10K 59/131; H10K 59/121

(52) U.S. Cl. CPC H10K 59/131; H10K 59/1213

(57) ABSTRACT

A display device comprising: a substrate; a driving voltage line on the substrate; a first extension electrode and a second extension electrode extending from the driving voltage line; a first pixel connection electrode disposed on the first extension electrode; a second pixel connection electrode disposed on the second extension electrode; a first pixel electrode connected to the first pixel connection electrode; and a second pixel electrode connected to the second pixel connection electrode, wherein at least a portion of the first extension electrode overlaps the first pixel connection electrode, and at least a portion of the second extension electrode overlaps the second pixel connection electrode.

### CROSS-REFERENCE TO RELATED APPLICATION(S)

This application claims priority to and benefits of Korean Patent Application No. 10-2024-0006710 under 35 U.S.C. 119, filed on Jan. 16, 2024, in the Korean Intellectual Property Office (KIPO), the entire contents of which are incorporated herein by reference.

### BACKGROUND

### 1. Technical Field

The disclosure relates to a display device that may simplify a manufacturing process and optimize a space.

### 2. Description of the Related Art

An organic light emitting display device includes a display element whose luminance is changed by current, for example, an organic light emitting diode.

The organic light emitting display device includes multiple pixels that provide light of different colors.

### SUMMARY

Aspects of the disclosure provide a display device capable of simplifying a manufacturing process and optimizing a space.

According to an embodiment of the disclosure, a display device may include a substrate; a driving voltage line on the substrate; a first extension electrode and a second extension electrode extending from the driving voltage line; a first pixel connection electrode disposed on the first extension electrode; a second pixel connection electrode disposed on the second extension electrode; a first pixel electrode connected to the first pixel connection electrode; and a second pixel electrode connected to the second pixel connection electrode, wherein at least a portion of the first extension electrode overlaps the first pixel connection electrode, and at least a portion of the second extension electrode overlaps the second pixel connection electrode.

In an embodiment, the first extension electrode and the first pixel connection electrode are connected to each other, and the second extension electrode and the second pixel connection electrode are connected to each other.

In an embodiment, further comprising a pixel defining film disposed on the first pixel electrode and the second pixel electrode.

In an embodiment, an overlapping portion between the first extension electrode and the first pixel connection electrode overlaps the pixel defining film, and an overlapping portion between the second extension electrode and the second pixel connection electrode overlaps the pixel defining film.

In an embodiment, further comprising: a first driving transistor connected between the first pixel connection electrode and the driving voltage line; a first switching transistor connected between a data line and a gate electrode of the first driving transistor; a first initialization transistor connected between the first pixel connection electrode and an initialization voltage line; and a first capacitor connected between the gate electrode of the first driving transistor and the first pixel connection electrode.

In an embodiment, at least one of the gate electrode of the first driving transistor, a gate electrode of the first switching transistor, and a gate electrode of the first initialization transistor is cut to be separated into at least two portions.

In an embodiment, the gate electrode of the first driving transistor is separated from a source electrode of the first switching transistor and the first capacitor.

In an embodiment, the gate electrode of the first switching transistor is separated from a first scan line.

In an embodiment, the gate electrode of the first initialization transistor is separated from a second scan line.

In an embodiment, the driving voltage line includes a lower driving voltage line and an upper driving voltage line that intersect each other and are connected to each other through a contact hole in an insulating film.

In an embodiment, at least a portion of the first extension electrode and a portion of the second extension electrode each overlap the lower driving voltage line.

In an embodiment, at least a portion of the first extension electrode and a portion of the second extension electrode is each connected to the lower driving voltage line.

In an embodiment, the lower driving voltage line is disposed on the same layer as the first extension electrode and the second extension electrode, and the upper driving voltage line is disposed on the same layer as the first pixel connection electrode and the second pixel connection electrode.

In an embodiment, the lower driving voltage line includes a repair electrode separated from the lower driving voltage line.

In an embodiment, the first extension electrode and the second extension electrode are connected to the repair electrode.

In an embodiment, the first extension electrode and the second extension electrode are formed integrally with the repair electrode.

In an embodiment, the upper driving voltage line connected to the repair electrode is cut on both sides so as not to be connected to other upper driving voltage lines.

In an embodiment, further comprising: a second driving transistor connected between the second pixel connection electrode and the driving voltage line; a second switching transistor connected between the data line and a gate electrode of the second driving transistor; a second initialization transistor connected between the second pixel connection electrode and the initialization voltage line; and a second capacitor connected between the gate electrode of the second driving transistor and the second pixel connection electrode.

In an embodiment, a source electrode of the second driving transistor is connected to the first pixel electrode through the second pixel connection electrode, a repair electrode separated from the driving voltage line, a second extension electrode connected to one side of the repair electrode and the second pixel connection electrode, and a first extension electrode connected to the other side of the repair electrode and the first pixel connection electrode.

In an embodiment, further comprising: a first light emitting layer connected to the first pixel electrode; and a second light emitting layer connected to the second pixel electrode, wherein the first light emitting layer and the second light emitting layer are light emitting layers that provide the same color.

According to the display device of an embodiment, the manufacturing process may be simplified and the space may be optimized.

However, aspects of the disclosure are not restricted to those set forth herein. The above and other aspects of the disclosure will become more apparent to one of ordinary skill in the art to which the disclosure pertains by referencing the detailed description of the disclosure given below.

### BRIEF DESCRIPTION OF THE DRAWINGS

The above and other aspects and features of the disclosure will become more apparent by describing in detail embodiments thereof with reference to the attached drawings, in which:

FIG. 1 is a schematic diagram of an equivalent circuit of a display device according to an embodiment;

FIG. 2 is a plan view of a display device according to an embodiment;

FIG. 3 is a plan view selectively illustrating only a first pattern layer among first to fifth pattern layers of FIG. 2;

FIG. 4 is a plan view selectively illustrating only the first and second pattern layers among the first to fifth pattern layers of FIG. 2;

FIG. 5 is a plan view selectively illustrating only the first, second, and third pattern layers among the first to fifth pattern layers of FIG. 2;

FIG. 6 is a plan view selectively illustrating only the first, second, third, and fourth pattern layers among the first to fifth pattern layers of FIG. 2;

FIG. 7 is a schematic cross-sectional view taken along line I-I′ of FIG. 2;

FIG. 8 is a schematic cross-sectional view taken along line II-II′ of FIG. 2;

FIG. 9 is a plan view of first to fourth pattern layers of a display device according to an embodiment;

FIG. 10 is a schematic cross-sectional view taken along line III-III′ of FIG. 9; and

FIG. 11 is a schematic cross-sectional view taken along the line IV-IV′ of FIG. 9.

### DETAILED DESCRIPTION OF THE EMBODIMENTS

Advantages and features of the disclosure and methods to achieve them will become apparent from the descriptions of embodiments hereinbelow with reference to the accompanying drawings. However, the disclosure is not limited to embodiments disclosed herein but may be implemented in various different ways. The embodiments are provided for making the disclosure of the disclosure thorough and for fully conveying the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the disclosure.

Features of various embodiments of the disclosure may be combined partially or totally. As will be clearly appreciated by those skilled in the art, technically various interactions and operations are possible. Various embodiments can be practiced individually or in combination.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, specific embodiments will be described with reference to the accompanying drawings.

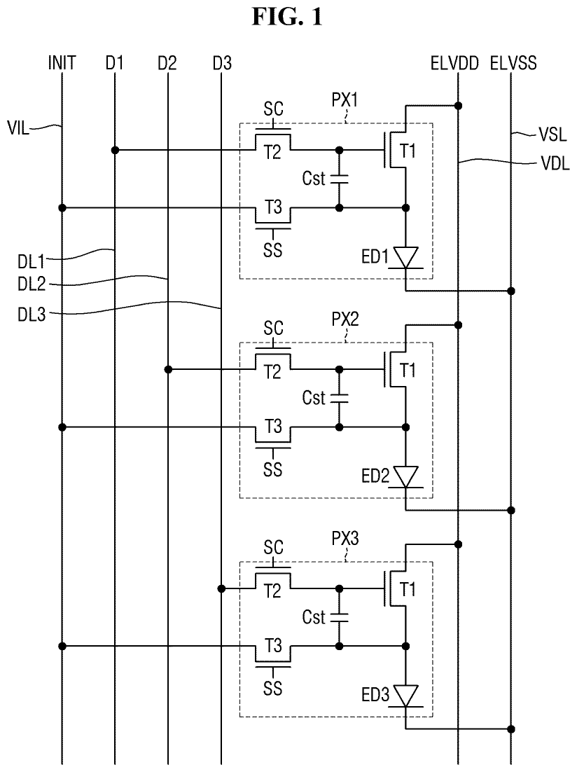

FIG. 1 is a schematic diagram of an equivalent circuit of a display device according to an embodiment.

A display device according to an embodiment may include multiple pixels. FIG. 1 schematically illustrates three adjacent pixels PX1, PX2, and PX3 among the pixels.

As illustrated in FIG. 1, the pixels may include a first pixel PX1, a second pixel PX2, and a third pixel PX3. Each of the first pixel PX1, the second pixel PX2, and the third pixel PX3 may include multiple transistors T1, T2, and T3, at least one capacitor Cst, and at least one light emitting diode, which is a light emitting element. For example, the first pixel PX1 may include a first light emitting element ED1, the second pixel PX2 may include a second light emitting element ED2, and the third pixel PX3 may include a third light emitting element ED3. The first light emitting element ED1, the second light emitting element ED2, and the third light emitting element ED3 may provide light of different colors. For example, the first light emitting element ED1 may include a light emitting layer that provides red light, the second light emitting element ED2 may include a light emitting layer that provides green light, and the third light emitting element ED3 may include a light emitting layer that provides blue light.

The first pixel PX1, the second pixel PX2, and the third pixel PX3 may have a same configuration. Hereinafter, the configuration of the first pixel PX1 will be representatively described.

The first pixel PX1 may include a pixel circuit and a light emitting element connected to the pixel circuit. The pixel circuit of the first pixel may include, for example, a driving transistor T1, a switching transistor T2, an initialization transistor T3, and a capacitor Cst.

A drain electrode and a source electrode of each of the transistors T1, T2, and T3, which will be explained below, are used to distinguish the two electrodes positioned on sides of a channel of each of the transistors T1, T2, and T3. Depending on a potential difference, the source electrode may be changed to the drain electrode, or the drain electrode may be changed to the source electrode.

A gate electrode of the driving transistor T1 may be connected to a first electrode of the capacitor Cst, a drain electrode of the driving transistor T1 may be connected to the driving voltage line VDL that transmits the driving voltage ELVDD, and a source electrode of the driving transistor T1 may be connected to an anode electrode of the light emitting element ED1 and a second electrode of the capacitor Cst. The driving transistor T1 may receive data voltages D1, D2, and D3 according to a switching operation of the switching transistor T2 and supply a driving current to the light emitting element ED1 according to the voltage stored in the capacitor Cst.

A gate electrode of the switching transistor T2 may be connected to a first scan line that transmits a first scan signal SC, a drain electrode of the switching transistor T2 may be connected to the data line that may transmit the data voltages D1, D2, and D3 or the reference voltage, and a source electrode of the switching transistor T2 may be connected to the first electrode of the capacitor Cst and the gate electrode of the driving transistor T1. The data lines DL1 to DL3 may transmit different data voltages D1, D2, and D3. The switching transistor T2 of each of the pixels PX1, PX2, and PX3 may be connected to different data lines DL1, DL2, and DL3. For example, the switching transistor T2 of the first pixel PX1 may be connected to the first data line DL1, the switching transistor T2 of the second pixel PX2 may be connected to the second data line DL2, and the switching transistor T2 of the third pixel PX3 may be connected to the third data line DL3.

The switching transistor T2 may be turned on according to the first scan signal SC from the first scan line and supply the reference voltage or the data voltage D1, D2, or D3 to the gate electrode of the driving transistor T1 and the first electrode of the capacitor Cst.

A gate electrode of the initialization transistor T3 may be connected to a second scan line that transmits a second scan signal SS from the second scan line, a drain electrode of the initialization transistor T3 may be connected to a second electrode of the capacitor Cst, the source electrode of the driving transistor T1, and the anode electrode of the light emitting element ED1, and a source electrode of the initialization transistor T3 may be connected to an initialization voltage line VIL that transmits an initialization voltage INIT. The initialization transistor T3 may be turned on according to the second scan signal SS and transmit the initialization voltage INIT to the anode electrode of the light emitting element ED1 and the second electrode of the capacitor Cst to initialize voltage of the anode electrode of the light emitting element ED1.

The first electrode of the capacitor Cst may be connected to the gate electrode of the driving transistor T1, and the second electrode of the capacitor Cst may be connected to the drain electrode of the initialization transistor T3 and the anode electrode of the light emitting element ED1. A cathode electrode CE of the light emitting element ED1 is connected to a common voltage line VSL that transmits a common voltage ELVSS.

The light emitting element ED1 may emit light with a luminance according to the driving current generated by the driving transistor T1.

An example of an operation of the circuit illustrated in FIG. 1, particularly an example of an operation during one frame, will be described as follows. Here, an example will be provided where the transistors T1, T2, and T3 are N-type channel transistors, but the disclosure is not limited.

In case that one frame starts, a high-level first scan signal SC and a high-level second scan signal SS may be supplied in an initialization period to turn on the switching transistor T2 and the initialization transistor T3. The reference voltage from the data line may be supplied to the gate electrode of the driving transistor T1 and one end of the capacitor Cst through the turned-on switching transistor T2, and the initialization voltage INIT may be supplied to the source electrode of the driving transistor T1 and the anode electrode of the light emitting element ED1 through the turned-on initialization transistor T3. Accordingly, during the initialization period, the source electrode of the driving transistor T1 and the anode electrode of the light emitting element ED1 may be initialized to the initialization voltage INIT, and a difference voltage between the reference voltage and the initialization voltage INIT may be stored in the capacitor Cst.

In case that the second scan signal SS becomes a low level in a state in which the high-level first scan signal SC is maintained in a sensing section, the switching transistor T2 may remain the turned-on state and the initialization transistor T3 may be turned off. The gate electrode of the driving transistor T1 and one end of the capacitor Cst maintain the reference voltage through the turned-on switching transistor T2, and the source electrode of the driving transistor T1 and the anode electrode of the light emitting element ED1 may be electrically separated from the initialization voltage line VIL through the turned-off initialization transistor T3. Accordingly, the driving transistor T1 may be turned off in case that a current flows from the drain electrode to the source electrode and a voltage of the source electrode reaches a “reference voltage-Vth”. Vth represents a threshold voltage of the driving transistor T1. A voltage difference between the gate electrode and the source electrode of the driving transistor T1 may be stored in the capacitor Cst, and sensing the threshold voltage Vth of the driving transistor T1 may be completed. As a data signal compensated based on characteristic information sensed during the sensing period is generated, deviations in characteristics of the driving transistor T1, which may differ for each pixel, may be externally compensated.

In case that a high-level first scan signal SC is supplied and a low-level second scan signal SS is supplied in a data input period, the switching transistor T2 may be turned on and the initialization transistor T3 may be turned off. The data voltages D1, D2, and D3 from the data lines DL1, DL2, and DL3 are supplied to the gate electrode of the driving transistor T1 and one end of the capacitor Cst through the turned-on switching transistor T2 of each of the pixels PX1, PX2, and PX3. The source electrode of the driving transistor T1 and the anode electrode of the light emitting element ED1 may maintain a potential in the sensing period almost as is due to the driving transistor T1, which is in the turned-off state.

In a light emitting period, the driving transistor T1 turned on by the data voltages D1, D2, and D3 transmitted to the gate electrode may generate a driving current according to the data voltages D1, D2, and D3, and the light emitting element ED1 may emit light due to the driving current.

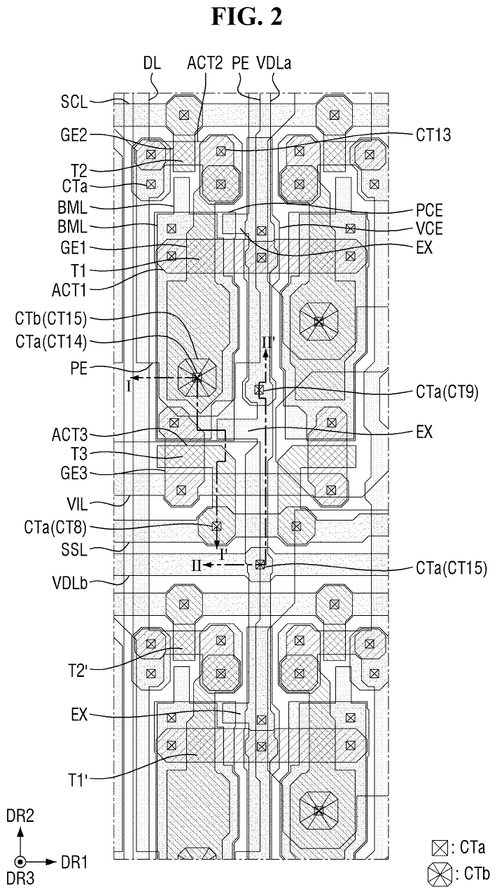

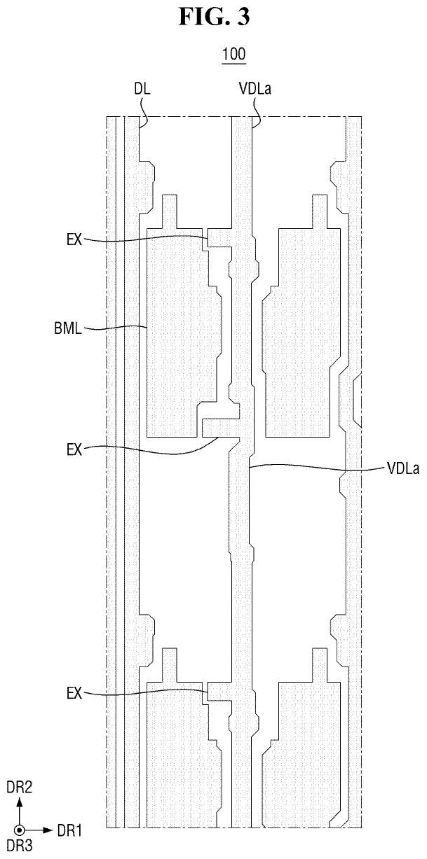

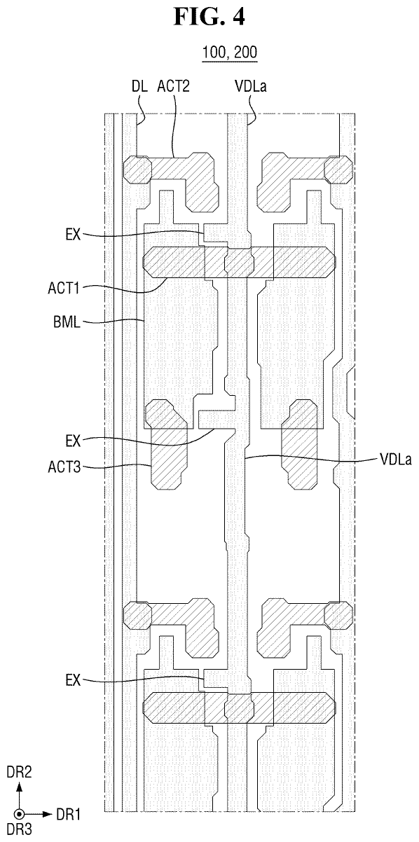

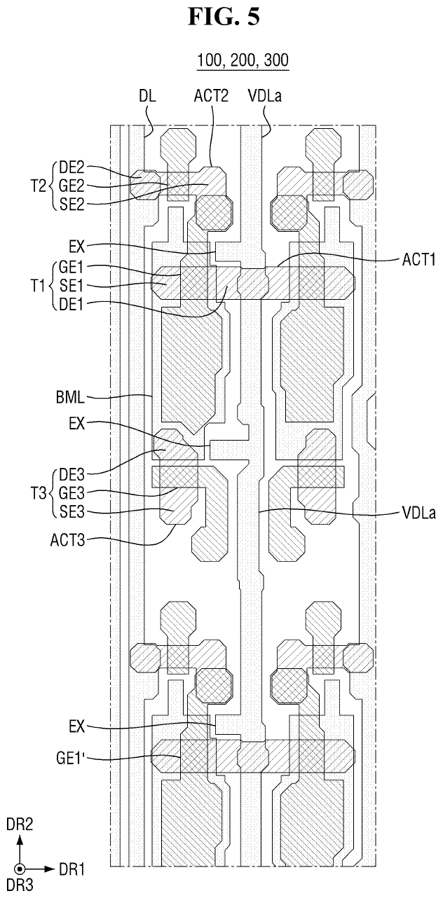

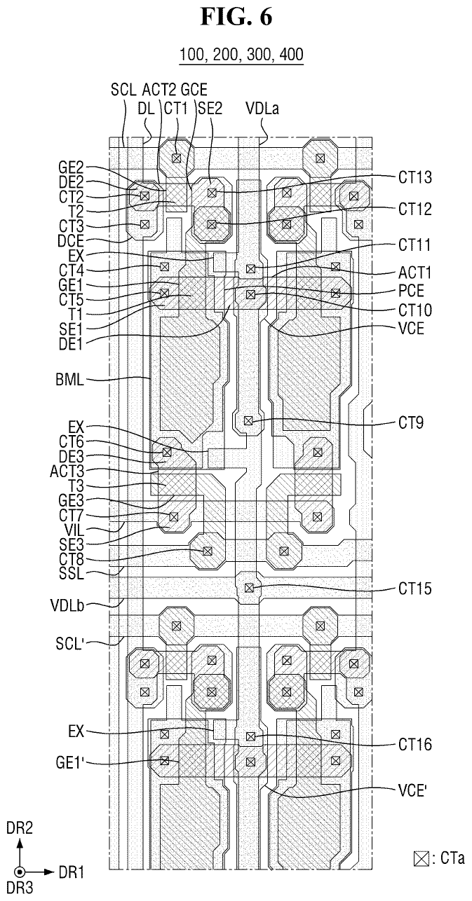

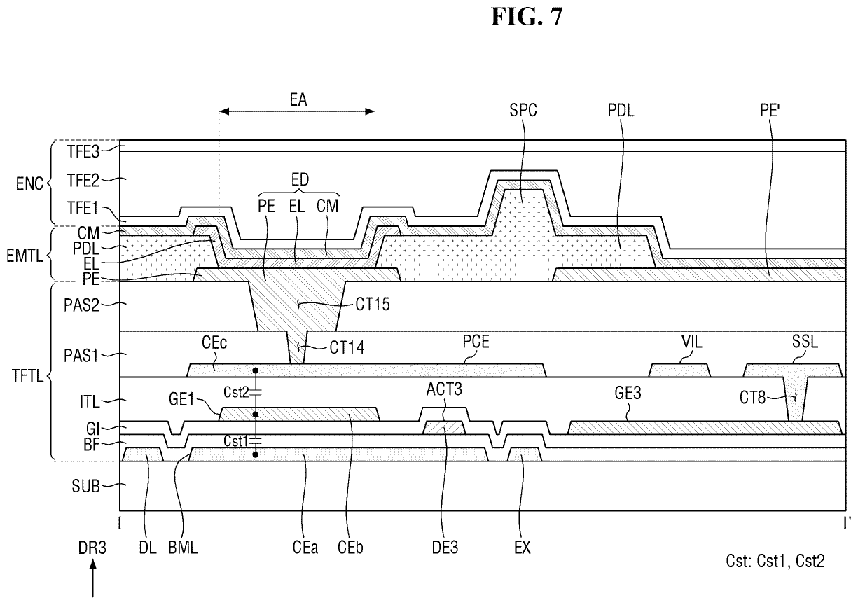

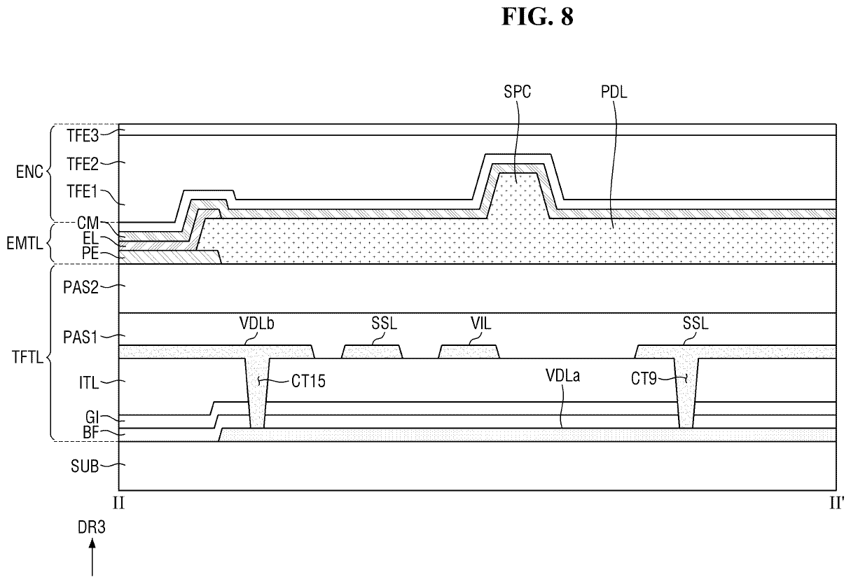

FIG. 2 is a plan view of a display device according to an embodiment, FIG. 3 is a plan view selectively illustrating only a first pattern layer 100 among first to fifth pattern layers of FIG. 2, FIG. 4 is a plan view selectively illustrating only the first and second pattern layers 100 and 200 among the first to fifth pattern layers of FIG. 2, FIG. 5 is a plan view selectively illustrating only the first, second, and third pattern layers 100, 200, and 300 among the first to fifth pattern layers of FIG. 2, FIG. 6 is a plan view selectively illustrating only the first, second, third, and fourth pattern layers 100, 200, 300, and 400 among the first to fifth pattern layers of FIG. 2, FIG. 7 is a schematic cross-sectional view taken along line I-I′ of FIG. 2, and FIG. 8 is a schematic cross-sectional view taken along line II-II′ of FIG. 2.

As illustrated in FIG. 2, the contact holes may be divided into a first type contact hole CTa and a second type contact hole CTb. The first type contact hole CTa may be a contact hole for connecting the fourth pattern layer 400 and the pattern layer below on a lower side thereof, and a contact hole for connecting the fourth pattern layer 400 and the pattern layer on a upper side thereof, and the second type contact hole CTb may be a contact hole for connecting the fifth pattern layer (e.g., PE and PE′) and the pattern layer on a lower side thereof.

As illustrated in FIGS. 7 and 8, the display device 10 may include a substrate SUB, a thin film transistor layer TFTL, a light emitting element layer EMTL, and an encapsulation layer ENC. The thin film transistor layer TFTL, the light emitting element layer EMTL, and the encapsulation layer ENC may be sequentially disposed on the substrate SUB along a third direction DR3. Here, the thin film transistor layer TFTL may include the driving transistor T1, the switching transistor T2, and the initialization transistor T3 that are described above.

The substrate SUB may be a rigid substrate or may be a flexible substrate capable of being bent, folded, rolled, or the like. The substrate SUB may be made of an insulating material such as glass, quartz, or a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP), or a combination thereof. In another embodiment, the substrate SUB may include a metal material.

As illustrated in FIGS. 7 and 8, a first pattern layer 100 may be disposed on the substrate SUB. The first pattern layer 100 may include, for example, a light blocking layer BML, a data line DL, a lower driving voltage line VDLa, and an extension electrode EX, as illustrated in FIGS. 2, 3, 7, and 8. The extension electrode EX may be formed integrally with the lower driving voltage line VDLa.

The light blocking layer BML may be formed of, for example, a metal material such as chromium (Cr) or molybdenum (Mo), or black ink or black dye. In case that the light blocking layer BML is formed of the metal material, the light blocking layer BML may receive a constant power. Through this, the light blocking layer BML may not be electrically floating, and electrical characteristics of the transistors on the light blocking layer BML may be stabilized.

The light blocking layer BML may include a lower capacitor electrode CEa. For example, a portion of the light blocking layer BML may be a lower capacitor electrode CEa.

The data line DL may extend along a second direction DR2.

The lower driving voltage line VDLa may extend along the second direction DR2.

The extension electrode EX may extend along a direction reverse to the first direction DR1 (hereinafter, referred to as first reverse direction). The extension electrode EX may extend from the lower driving voltage line VDLa in the first reverse direction. The extension electrodes EX may be provided in plurality, and multiple extension electrodes EX may extend from different portions of the lower driving voltage line VDLa in the first reverse direction.

A buffer film BF may be disposed on the first pattern layer 100. For example, as in the example illustrated in FIGS. 7 and 8, the buffer film BF may be disposed on the light blocking layer BML, the data line DL, the lower driving voltage line VDLa, and the extension electrode EX. The buffer film BF may be a film for protecting the transistors T1 to T3 of the thin film transistor layer TFTL and the light emitting layer EL of the light emitting element layer EMTL from moisture permeating through the substrate SUB that is vulnerable to moisture permeation. The buffer film BF may include multiple inorganic films that are alternately stacked each other. For example, the buffer film BF may be formed as a multi-film in which one or more inorganic films of a silicon nitride layer, a silicon oxynitride layer, a silicon oxide layer, a titanium oxide layer, and an aluminum oxide layer are alternately stacked each other.

The second pattern layer 200 may be disposed on the buffer film BF. As illustrated in FIG. 4, the second pattern layer 200 may include a first active layer ACT1, a second active layer ACT2, and a third active layer ACT3. The first active layer ACT1, the second active layer ACT2, and the third active layer ACT3 may overlap the first pattern layer 100 on a lower side thereof. For example, as illustrated in FIG. 4, the first active layer ACT1 and the third active layer ACT3 may be disposed on the buffer film BF to overlap the light blocking layer BML, and the second active layer ACT2 may be disposed on the buffer film BF to overlap the data line DL. FIG. 7 illustrates an example in which the third active layer ACT3 is disposed on the buffer film BF to overlap the light blocking layer BML.

The first active layer ACT1, the second active layer ACT2, and the third active layer ACT3 may be active layers made of low temperature polycrystalline silicon (LTPS). In another embodiment, the first active layer ACT1, the second active layer ACT2, and the third active layer ACT3 may be oxide-based active layers. For example, each of the first active layer ACT1, the second active layer ACT2, and the third active layer ACT3 may be an oxide semiconductor including indium-gallium-zinc-oxide (IGZO) or indium-gallium-zinc-tin oxide (IGZTO).

As illustrated in FIGS. 7 and 8, a gate insulating film GTI may be disposed on the second pattern layer 200. For example, as illustrated in FIG. 7, the gate insulating film GTI may be disposed on the third active layer ACT3.

The gate insulating film GTI may include at least one of tetraethoxysilane (TetraEthylOrthoSilicate, TEOS), silicon nitride (SiNx), and silicon oxide (SiO₂). As an example, the gate insulating film GTI may have a double film structure in which a silicon nitride film having a thickness of 40 nm and a tetraethoxysilane film having a thickness of 80 nm are sequentially stacked.

A third pattern layer 300 may be disposed on the gate insulating film GTI. As illustrated in FIG. 5, the third pattern layer 300 may include a first gate electrode GE1, a second gate electrode GE2, and a third gate electrode GE3. The first gate electrode GE1 may be disposed on the gate insulating film GTI to overlap the first active layer ACT1, the second gate electrode GE2 may be disposed on the gate insulating film GTI to overlap the second active layer ACT2, and the third gate electrode GE3 may be disposed on the gate insulating film GTI to overlap the third active layer ACT3.

The first gate electrode GE1 may include an intermediate capacitor electrode CEb. A portion of the first gate electrode GE1 that overlaps the above-described light blocking layer BML may be the intermediate capacitor electrode CEb. For example, the intermediate capacitor electrode CEb of the first gate electrode GE1 and the lower capacitor electrode CEa of the light blocking layer BML may overlap each other. A first storage capacitor Cst1 may be formed between the intermediate capacitor electrode CEb and the lower capacitor electrode CEa.

An area of the first active layer ACT1 that overlaps the first gate electrode GE1 may be a channel area of the driving transistor T1, and two areas of the first active layer ACT1 that do not overlap the first gate electrode GE1 and are divided two-dimensionally by the first gate electrode GE1 may be a first drain electrode DE1 and a first source electrode SE1 of the driving transistor T1, respectively.

An area of the second active layer ACT2 that overlaps the second gate electrode GE2 may be a channel area of the switching transistor T2, and two areas of the second active layer ACT2 that do not overlap the second gate electrode GE2 and are divided two-dimensionally by the second gate electrode GE2 may be a second drain electrode DE2 and a second source electrode SE2 of the switching transistor T2, respectively.

An area of the third active layer ACT3 that overlaps the third gate electrode GE3 may be a channel area of the initialization transistor T3, and two areas of the third active layer ACT3 that do not overlap the third gate electrode GE3 and are divided two-dimensionally by the third gate electrode GE3 may be a third drain electrode DE3 and a third source electrode SE3 of the initialization transistor T3, respectively.

T1′ and T2′ in FIGS. 2 and 5 refer to a driving transistor T1 and a switching transistor T2 of different pixels, respectively, and GE1′ in FIG. 5 refers to a first gate electrode of the driving transistor T1′. The above-described third pattern layer 300 may further include the gate electrode GE1′.

An interlayer insulating film ITL may be disposed on the third pattern layer 300. For example, as illustrated in FIGS. 7 and 8, the interlayer insulating film ITL may be disposed on the first gate electrode GE1 and the third gate electrode GE3.

The interlayer insulating film ITL may include an inorganic film, for example, a silicon nitride layer, a silicon oxynitride layer, a silicon oxide layer, a titanium oxide layer, or an aluminum oxide layer. The interlayer insulating film ITL may include multiple inorganic films.

A fourth pattern layer 400 may be disposed on the interlayer insulating film ITL. As illustrated in FIGS. 2 and 6, the fourth pattern layer 400 may include a pixel connection electrode PCE, a gate connection electrode GCE, a power connection electrode VCE, a first scan line SCL, a second scan line SSL, an initialization voltage line VIL, and an upper driving voltage line VDLb. FIGS. 7 and 8 illustrate an example in which the pixel connection electrode PCE, the power connection electrode VCE, the second scan line SSL, the initialization voltage line VIL, and the upper driving voltage line VDLb are disposed on the interlayer insulating film ITL.

As illustrated in FIG. 6, the pixel connection electrode PCE may be connected to the light blocking layer BML through a fourth contact hole CT4 penetrating through the interlayer insulating film ITL, the gate insulating film GTI, and the buffer film BF. As illustrated in FIG. 6, the pixel connection electrode PCE may be connected to the first source electrode SE1 of the driving transistor T1 through a fifth contact hole CT5 penetrating through the interlayer insulating film ITL and the gate insulating film GTI. As illustrated in FIG. 6, the pixel connection electrode PCE may be connected to the third drain electrode DE3 of the initialization transistor T3 through a sixth contact hole CT6 penetrating through the interlayer insulating film ITL and the gate insulating film GTI. The pixel connection electrode PCE may include an upper capacitor electrode CEc. A portion of the pixel connection electrode PCE that overlaps the above-described first gate electrode GE1 may be the upper capacitor electrode CEc. For example, the upper capacitor electrode CEc of the pixel connection electrode PCE and the intermediate capacitor electrode CEb of the first gate electrode GE1 may overlap each other. A second storage capacitor Cst2 may be formed between the upper capacitor electrode CEc and the intermediate capacitor electrode CEb. The capacitor Cst of FIG. 1 described above may include the first storage capacitor Cst1 and the second storage capacitor Cst2. As illustrated in FIGS. 6 and 7, at least a portion of the pixel connection electrode PCE may overlap the extension electrode EX.

As illustrated in FIG. 6, the gate connection electrode GCE may be connected to the first gate electrode GE1 of the driving transistor T1 through a twelfth contact hole CT12 penetrating through the interlayer insulating film ITL. As illustrated in FIG. 6, the pixel connection electrode PCE may be connected to the second source electrode SE2 of the switching transistor T2 through a thirteenth contact hole CT13 penetrating through the interlayer insulating film ITL and the gate insulating film GTI.

As illustrated in FIGS. 6 and 8, the power connection electrode VCE may be connected to the lower driving voltage line VDLa through a ninth contact hole CT9 and an eleventh contact hole CT11 penetrating through the interlayer insulating film ITL, the gate insulating film GTI, and the buffer film BF. As illustrated in FIG. 6, the power connection electrode VCE may be connected to the first drain electrode DE1 of the driving transistor T1 through a tenth contact hole CT10 penetrating through the interlayer insulating film ITL and the gate insulating film GTI.

As illustrated in FIG. 6, the first scan line SCL may be connected to the second gate electrode GE2 of the switching transistor T2 through a first contact hole CT1 penetrating through the interlayer insulating film ITL.

As illustrated in FIGS. 6 and 7, the second scan line SSL may be connected to the third gate electrode GE3 of the initialization transistor T3 through an eighth contact hole CT8 penetrating through the interlayer insulating film ITL.

As illustrated in FIG. 6, the initialization voltage line VIL may be connected to the third source electrode SE3 of the initialization transistor T3 through a seventh contact hole CT7 penetrating through the interlayer insulating film ITL and the gate insulating film GTI.

As illustrated in FIGS. 6 and 8, the upper driving voltage line VDLb may be connected to the lower driving voltage line VDLa through a fifteenth contact hole CT15 penetrating through the interlayer insulating film ITL, the gate insulating film GTI, and the buffer film BF.

A first passivation layer PAS1 may be disposed on the fourth pattern layer 400. For example, as illustrated in FIGS. 7 and 8, the first passivation layer PAS1 may be disposed on the power connection electrode VCE, the second scan line SSL, the initialization voltage line VIL, and the upper driving voltage line VDLb.

The first passivation layer PAS1 may include an organic film made of an acryl resin, an epoxy resin, a phenolic resin, a polyamide resin, a polyimide resin, or the like.

A second passivation layer PAS2 may be disposed on the first passivation layer PAS1. For example, as illustrated in FIGS. 7 and 8, the second passivation layer PAS2 may be disposed on the first passivation layer PAS1. The second passivation layer PAS2 may have an etch ratio different from that of the first passivation layer PAS1. The second passivation layer PAS2 and the above-described first passivation layer PAS1 may have a same material and a same structure. However, the first passivation layer PAS1 may have a higher etch ratio than the second passivation layer PAS2.

A fifth pattern layer may be disposed on the second passivation layer PAS2. For example, as illustrated in FIGS. 7 and 8, a light emitting element layer EMTL including a fifth pattern layer may be disposed on the second passivation layer PAS2. In other words, a pixel electrode PE may be disposed as the fifth pattern layer on the second passivation layer PAS2. The pixel electrode PE may be connected to the pixel connection electrode PCE through the fifteenth contact hole CT15 penetrating through the first passivation layer PAS1 and the fourteenth contact hole CT14 penetrating through the first passivation layer PAS1. Here, the fifteenth contact hole CT15 and the fourteenth contact hole CT14 may be connected to each other. In plan view, the fifteenth contact hole CT15 may completely overlap the fourteenth contact hole CT14. The above-described fourteenth contact hole CT14 may belong to the first type contact hole CTa, and the fifteenth contact hole CT15 may belong to the second type contact hole CTb.

The above-described light emitting element layer EMTL may include a light emitting element ED and a pixel defining film PDL.

The light emitting element ED may include a pixel electrode PE, a light emitting layer EL, and a common electrode CM. The light emitting area EA refers to an area in which the pixel electrode PE, the light emitting layer EL, and the common electrode CM are sequentially stacked and holes from the pixel electrode PE and electrons from the common electrode CM are bonded to each other in the light emitting layer EL to emit light. The pixel electrode PE may be an anode electrode of the light emitting element ED, and the common electrode CM may be a cathode electrode of the light emitting element ED.

In a top emission structure that emits light in a direction of the common electrode CM based on the light emitting layer EL, the pixel electrode may be formed as a single layer made of molybdenum (Mo), titanium (Ti), copper (Cu), or aluminum (Al) or be formed as a stacked structure (Ti/Al/Ti) of aluminum and titanium, a stacked structure (ITO/AI/ITO) of aluminum and ITO, an APC alloy, and a stacked structure (ITO/APC/ITO) of an APC alloy and ITO. The APC alloy may be an alloy of silver (Ag), palladium (Pd), and copper (Cu).

The pixel defining film PDL serves to define the light emitting areas EA of the pixel. To this end, the pixel defining film PDL may be disposed on the second passivation layer PAS2 to expose a partial area of the pixel electrode PE. The pixel defining film PDL may cover each edge of the pixel electrode PE.

The pixel defining film PDL may be formed as an organic film made of an acryl resin, an epoxy resin, a phenolic resin, a polyamide resin, a polyimide resin, or the like.

As illustrated in FIGS. 7 and 8, a spacer SPC may be disposed on the pixel defining film PDL. The spacer SPC may serve to support a mask during a process of manufacturing the light emitting layer EL. The spacer SPC may be formed as an organic film made of an acryl resin, an epoxy resin, a phenolic resin, a polyamide resin, or a polyimide resin. In an embodiment, the spacer SPC may be formed integrally with the pixel defining film PDL. In other words, the spacer SPC and the pixel defining film PDL may be made of a same material.

A light emitting layer EL may be formed on the pixel electrode PE. The light emitting layer EL may include an organic material to emit light of a color. For example, the light emitting layer EL may include a hole transporting layer, an organic material layer, and an electron transporting layer. The organic material layer may include a host and a dopant. The organic material layer may include a material that emits a light and may be formed of a phosphorescent material or a fluorescent material.

For example, the organic material layer of the light emitting layer EL that emits light of a third color (e.g., blue) may be a phosphorescent material including a host material including CBP or mCP and including a dopant material including (4,6-F2ppy)2Irpic or L2BD111, but is not limited thereto.

The organic material layer of the light emitting layer EL that emits light of a second color (e.g., green) may be a phosphorescent material including a host material including CBP or mCP and a dopant material including Ir(ppy)3(fac tris(2-phenylpyridine) iridium). In another embodiment, the organic material layer of the light emitting layer EL that emits light of the second color may be a fluorescent material including Alq3(tris(8-hydroxyquinolino)aluminum), but is not limited thereto.

The organic material layer of the light emitting layer EL that emits light of a third color (e.g., red) may be a phosphorescent material including a host material including carbazole biphenyl (CBP) or mCP (1,3-bis(carbazol-9-yl), and including a dopant containing any one or more selected among PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and PtOEP(octaethylporphyrin platinum). In another embodiment, the organic material layer of the light emitting layer EL that emits light of the third color may be a fluorescent material including PBD:Eu(DBM)3(Phen) or perylene, but is not limited thereto.

The common electrode CM may be disposed on the light emitting layer EL. The common electrode CM may be disposed to cover the light emitting layer EL. The common electrode CM may be a common layer commonly disposed on the light emitting layers EL. A capping layer may be formed on the common electrode CM.

In the top emission structure, the common electrode CM may be formed of a transparent conductive material (TCO) such as ITO or IZO capable of transmitting light, or a semi-transmissive conductive material such as magnesium (Mg), silver (Ag), or an alloy of magnesium (Mg) and silver (Ag). In case that the common electrode CM is formed of the semi-transmissive conductive material, light emission efficiency may be increased by a micro cavity.

The encapsulation layer ENC may be disposed on the light emitting element layer EMTL. The encapsulation layer ENC may include one or more inorganic films TFE1 and TFE3 to prevent oxygen or moisture from permeating into the light emitting element layer EMTL. The encapsulation layer ENC may include at least one organic film to protect the light emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed as a multi-film in which one or more inorganic films of a silicon nitride layer, a silicon oxynitride layer, a silicon oxide layer, a titanium oxide layer, and an aluminum oxide layer are alternately stacked each other. The encapsulation organic film TFE2 may be an organic film made of an acrylic resin, an epoxy resin, a phenolic resin, a polyamide resin, or a polyimide resin.

An overlapping portion between the extension electrode EX and the pixel connection electrode PCE may overlap, for example, the above-described pixel defining film PDL in the third direction DR3. The overlapping portion between each pixel connection electrode PCE and each extension electrode EX of each pixel may overlap the pixel defining film PDL described above.

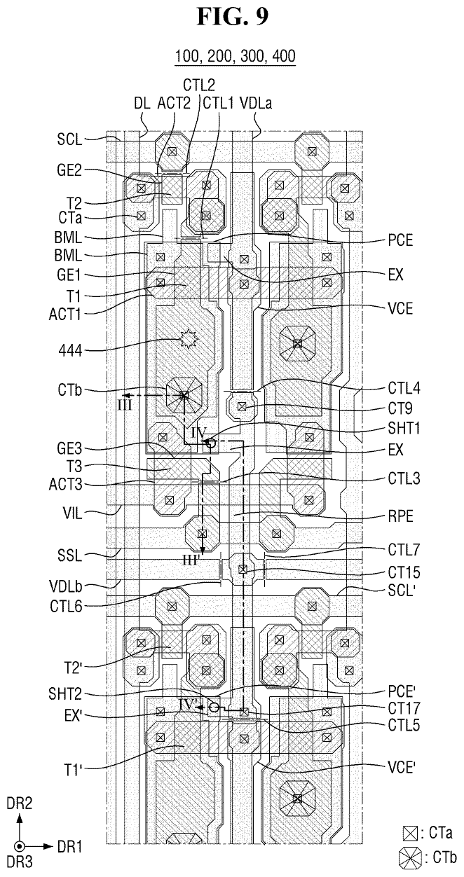

Hereinafter, a repair method for the display device of FIG. 2 will be described with reference to FIGS. 9 to 11 as follows.

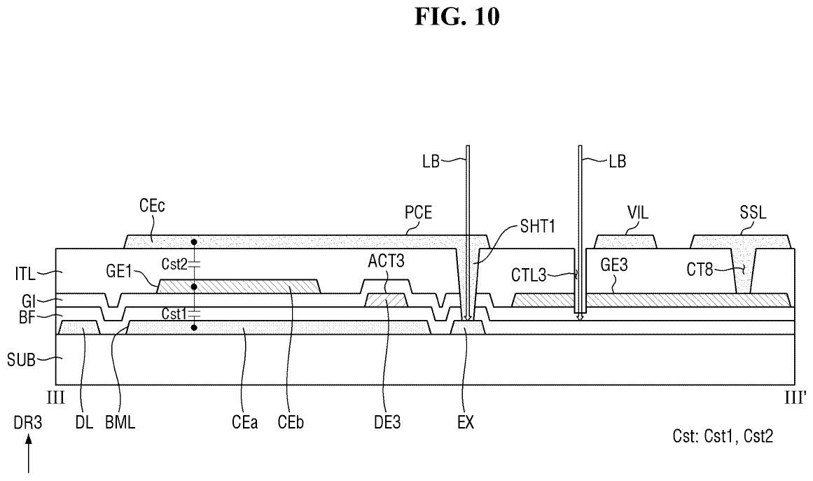

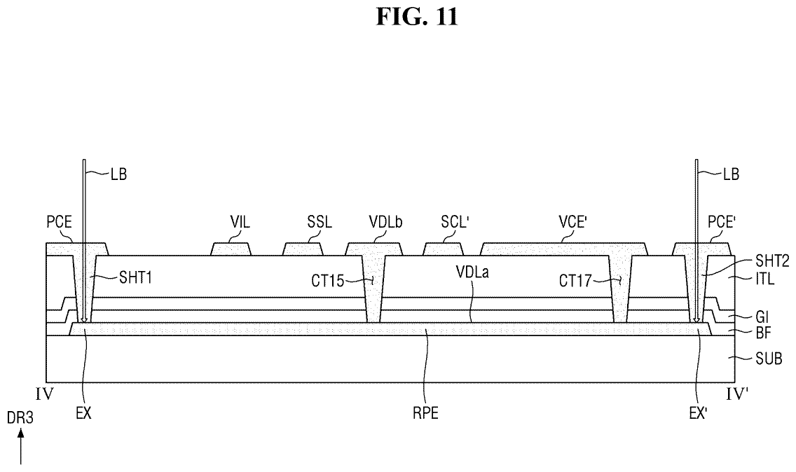

FIG. 9 is a plan view of first to fourth pattern layers of a display device according to an embodiment, FIG. 10 is a schematic cross-sectional view taken along line III-III′ of FIG. 9, and FIG. 11 is a schematic cross-sectional view taken along the line IV-IV′ of FIG. 9.

As illustrated in FIG. 9, if an abnormality occurs in a pixel (e.g., any one of the first pixel PX1, the second pixel PX2, and the third pixel PX3) due to a foreign matter 444 permeating into the pixel, and the pixel is determined to be a defective pixel that may not normally provide light, a repair process for the defective pixel may be performed, and such a repair process will be described in detail as follows.

First, each gate electrode of transistors of the defective pixel may be cut so that the transistors (e.g., T1, T2, and T3 of the defective pixel) of the defective pixel do not operate. For example, as illustrated in FIG. 9, the first gate electrode GE1 of the driving transistor T1 may be cut along a first cutting line CTL1, the second gate electrode GE2 of the switching transistor T2 may be cut along a second cutting line CTL2, and the third gate electrode GE3 of the initialization transistor T3 may be cut along a third cutting line CTL3.

Accordingly, the first gate electrode GE1 of the driving transistor T1 and the second source electrode SE2 of the switching transistor T2 may be electrically separated, the first gate electrode GE1 of the driving transistor T1 and the first electrode (e.g., the intermediate capacitor electrode CEb) of the capacitor may be electrically separated, the second gate electrode GE2 of the switching transistor T2 and the first scan line SCL may be electrically separated, and the third gate electrode GE3 of the initialization transistor T3 and the second scan line SSL may be electrically separated.

As illustrated in FIG. 9, in order to use a portion of the lower driving voltage line VDLa as a repair electrode RPE, the lower driving voltage line VDLa may be cut along two cutting lines CTL4 and CTL5. For example, as illustrated in FIG. 9, the lower driving voltage line VDLa may be cut along a fourth cutting line CTL4 and a fifth cutting line CTL5. Such a cut portion, for example, a lower driving voltage line portion disposed between the fourth cutting line CTL4 and the fifth cutting line CTL5, may be used as the repair electrode RPE. Hereinafter, the lower driving voltage line portion disposed between the fourth cutting line CTL4 and the fifth cutting line CTL5 will be referred to as the repair electrode RPE.

Although a portion of the lower driving voltage line VDLa is disconnected by the above-described cutting process, other normal pixels may be normally supplied with the driving voltage ELVDD, because the driving voltage line VDL has a mesh structure in which multiple lower driving voltage lines VDLa and multiple upper driving voltage lines VDLb are connected to each other at their intersection points.

As illustrated in FIG. 9, the repair electrode RPE may include at least two extension electrodes EX and EX′. One (hereinafter, a first extension electrode EX) of the two extension electrodes EX and EX′ of the repair electrode RPE may be disposed adjacent to the defective pixel, and another one (hereinafter, a second extension electrode EX′) of the two extension electrodes EX and EX′ of the repair electrode RPE may be disposed adjacent to another pixel (hereinafter, a normal pixel) connected to a same data line DL as the defective pixel. The first extension electrode EX of the repair electrode RPE may overlap a pixel connection electrode PCE (hereinafter, referred to as a first pixel connection electrode PCE) of the defective pixel and the second extension electrode EX′ thereof may overlap a pixel connection electrode PCE′ (hereinafter, a second pixel connection electrode PCE′) of the normal pixel.

Subsequently, in order to block an electrical connection between the repair electrode RPE and the upper driving voltage line VDLb, the upper driving voltage line VDLb may be cut near the fifteenth contact hole CT15 where the repair electrode RPE and the upper driving voltage line VDLb are connected. For example, as illustrated in FIG. 9, the upper driving voltage line VDLb may be cut along a sixth cutting line CTL6 and a seventh cutting line CTL7, respectively. As a result, the repair electrode RPE may be maintained in an electrically floating state.

The above-described cutting process may be performed, for example, by irradiating a laser beam LB along each cutting line. As illustrated in FIG. 10, by irradiating the laser beam LB to the third gate electrode GE3 along the third cutting line CTL3 from the top of the substrate SUB, the third gate electrode GE3 may be divided into two portions.

Although a portion of the upper driving voltage line VDLb is disconnected by the above-described cutting process, other normal pixels may be normally supplied with the driving voltage ELVDD, because the driving voltage line VDL has the mesh structure as described above.

Thereafter, a process of electrically connecting the first extension electrode EX of the repair electrode RPE and the first pixel connection electrode PCE and electrically connecting the second extension electrode EX′ of the repair electrode RPE and the second pixel connection electrode PCE′ may be performed. For example, as illustrated in FIGS. 9 and 11, by irradiating the laser beam LB onto the first extension electrode EX that overlaps the first pixel connection electrode PCE, the first extension electrode EX and the first pixel connection electrode PCE may be connected to each other, and by irradiating the laser beam LB onto the second extension electrode EX′ that overlaps the second pixel connection electrode PCE′, the second extension electrode EX′ and the second pixel connection electrode PCE′ may be connected to each other. For example, as illustrated in FIG. 11, as a shorted portion SHT1 (hereinafter, referred to as a first shorted portion SHT1) of the first pixel connection electrode PCE is in contact with a side of the repair electrode RPE by the laser beam LB, a shorted portion SHT2 (hereinafter, referred to as a second shorted portion SHT2) of the second pixel connection electrode PCE′ may be in contact with another side of the repair electrode RPE by the laser beam LB. Here, the first shorted portion SHT1 and the second shorted portion SHT2 may be formed by melting the first pixel connection electrode PCE and the second pixel connection electrode PCE′, respectively, by the laser beam LB.

Subsequently, a first passivation layer PAS1, a second passivation layer PAS2, a light emitting element layer EMTL, and an encapsulation layer ENC may be formed. The pixel electrode PE (hereinafter, referred to as a first pixel electrode PE) of the defective pixel may be connected to the first pixel connection electrode PCE, and the pixel electrode PE′ (hereinafter, a second pixel electrode PE′) of the normal pixel may be connected to the second pixel connection electrode PCE′. Accordingly, the second pixel electrode PE′ of the normal pixel may be connected to the first pixel electrode PE of the defective pixel through the second pixel connection electrode PCE′, the second short portion SHT2, the repair electrode RPE, the first short portion SHT1, and the first pixel connection electrode PCE described above. In other words, the first source electrode SE1 of the driving transistor T1 included in the normal pixel may be connected to the first pixel electrode PE through the second pixel connection electrode PCE′, the repair electrode RPE separated from the lower driving voltage line VDLa, the second extension electrode EX′ connected to a side of the repair electrode RPE and the second pixel connection electrode PCE′, and the first extension electrode EX connected to another side of the repair electrode RPE and the first pixel connection electrode PCE. Therefore, in case that the data voltage (e.g., the data voltage of the normal pixel) is applied to the data line DL commonly connected to the defective pixel and the normal pixel, and the data voltage is provided to the second pixel electrode PE′ of the normal pixel, the data voltage may be applied not only to the first pixel electrode PE but also to the second pixel electrode PE′. Therefore, in case that the normal pixel emits light according to the data voltage, the defective pixel may also emit light according to the data voltage. Accordingly, the defective pixel may also emit light normally. In other words, the defective pixel may emit light normally by the data voltage of the normal pixel. Therefore, the defective pixel may become a bright spot.

The defective pixel and the normal pixel described above may be pixels that emit light of a same color. For example, the defective pixel and the normal pixel may be pixels that include a green light emitting layer.

As described above, according to the display device according to an embodiment, the manufacturing process may be simplified because a portion of the existing power line (e.g., the lower driving voltage line VDLa) is used as the repair electrode RPE without an additional repair line or repair electrode. A space of pixels may be optimized.

According to an embodiment, since the light emitting element of the defective pixel and the light emitting element of the normal pixel emit light through the driving current provided by one normal pixel, the luminance of the defective pixel and the normal pixel may be reduced. However, such a problem of reduction in luminance may be solved through an external compensation circuit. For example, the external compensation circuit may correct the data voltage corresponding to the normal pixel connected to the defective pixel to have a value greater than an original value. Therefore, a data voltage applied to the normal pixel of a pair of pixels (e.g., the defective pixel and the normal pixel connected to each other) may be a data voltage corrected to a higher value as described above.

As illustrated in FIGS. 9 and 11, the power connection line VCE′ may be connected to the repair electrode RPE through a seventeenth contact hole CT17 penetrating through the interlayer insulating film ITL, the gate insulating film GI, and the buffer film BF.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate;
a driving voltage line on the substrate;
a first extension electrode and a second extension electrode extending from the driving voltage line;
a first pixel connection electrode disposed on the first extension electrode;
a second pixel connection electrode disposed on the second extension electrode;
a first pixel electrode connected to the first pixel connection electrode; and
a second pixel electrode connected to the second pixel connection electrode,
wherein at least a portion of the first extension electrode overlaps the first pixel connection electrode, and
at least a portion of the second extension electrode overlaps the second pixel connection electrode.

2. The display device of claim 1, wherein the first extension electrode and the first pixel connection electrode are connected to each other, and
the second extension electrode and the second pixel connection electrode are connected to each other.

3. The display device of claim 1, further comprising a pixel defining film disposed on the first pixel electrode and the second pixel electrode.

4. The display device of claim 3, wherein an overlapping portion between the first extension electrode and the first pixel connection electrode overlaps the pixel defining film, and
an overlapping portion between the second extension electrode and the second pixel connection electrode overlaps the pixel defining film.

5. The display device of claim 1, further comprising:
a first driving transistor connected between the first pixel connection electrode and the driving voltage line;
a first switching transistor connected between a data line and a gate electrode of the first driving transistor;
a first initialization transistor connected between the first pixel connection electrode and an initialization voltage line; and
a first capacitor connected between the gate electrode of the first driving transistor and the first pixel connection electrode.

6. The display device of claim 5, wherein at least one of the gate electrode of the first driving transistor, a gate electrode of the first switching transistor, and a gate electrode of the first initialization transistor is cut to be separated into at least two portions.

7. The display device of claim 6, wherein the gate electrode of the first driving transistor is separated from a source electrode of the first switching transistor and the first capacitor.

8. The display device of claim 6, wherein the gate electrode of the first switching transistor is separated from a first scan line.

9. The display device of claim 6, wherein the gate electrode of the first initialization transistor is separated from a second scan line.

10. The display device of claim 1, wherein the driving voltage line includes a lower driving voltage line and an upper driving voltage line that intersect each other and are connected to each other through a contact hole in an insulating film.

11. The display device of claim 10, wherein at least a portion of the first extension electrode and a portion of the second extension electrode each overlap the lower driving voltage line.

12. The display device of claim 11, wherein at least a portion of the first extension electrode and a portion of the second extension electrode is each connected to the lower driving voltage line.

13. The display device of claim 10, wherein
the lower driving voltage line, the first extension electrode, and the second extension electrode are disposed on a same layer, and
the upper driving voltage line, the first pixel connection electrode, and the second pixel connection electrode are disposed on a same layer.

14. The display device of claim 10, wherein the lower driving voltage line includes a repair electrode separated from the lower driving voltage line.

15. The display device of claim 14, wherein the first extension electrode and the second extension electrode are connected to the repair electrode.

16. The display device of claim 15, wherein the first extension electrode and the second extension electrode are formed integrally with the repair electrode.

17. The display device of claim 14, wherein the upper driving voltage line connected to the repair electrode is cut on both sides so as not to be connected to other upper driving voltage lines.

18. The display device of claim 5, further comprising:
a second driving transistor connected between the second pixel connection electrode and the driving voltage line;
a second switching transistor connected between the data line and a gate electrode of the second driving transistor;
a second initialization transistor connected between the second pixel connection electrode and the initialization voltage line; and
a second capacitor connected between the gate electrode of the second driving transistor and the second pixel connection electrode.

19. The display device of claim 18, wherein a source electrode of the second driving transistor is connected to the first pixel electrode through the second pixel connection electrode, a repair electrode separated from the driving voltage line, a second extension electrode connected to a side of the repair electrode and the second pixel connection electrode, and a first extension electrode connected to another side of the repair electrode and the first pixel connection electrode.

20. The display device of claim 1, further comprising:
a first light emitting layer connected to the first pixel electrode; and
a second light emitting layer connected to the second pixel electrode,
wherein the first light emitting layer and the second light emitting layer are light emitting layers that provide a same color.
